(19) United States
(12) Patent Application Publication
(10) Pub. No.: US 2014/0247679 A1
(43) Pub. Date: Sep. 4, 2014

(54) SEMICONDUCTOR STORAGE DEVICE AND TESTING METHOD

(71) Applicant: FUJITSU LIMITED, Kawasaki-shi (JP)

(72) Inventor: Seiji Murata, Kawasaki (JP)

(73) Assignee: FUJITSU LIMITED, Kawasaki-shi (JP)

(21) Appl. No.: 14/277,856

(22) Filed: May 15, 2014

Related U.S. Application Data
(63) Continuation of application No. PCT/JP2011/077580, filed on Nov. 29, 2011.

(51) Int. Cl. G11C 29/12; G11C 29/00

(52) U.S. Cl. CPC G11C 29/12; G11C 29/70
USPC 365/200

(57) ABSTRACT

A plurality of writing circuits respectively writes data to a plurality of memory cell arrays and a redundant cell array. A holding circuit, which is arranged for each memory cell array, holds data input as a storage target. A first selection circuit, which is arranged for each of the writing circuits of the memory cell arrays, selects data to be output to the writing circuits from among pieces of data input from the holding circuit of the memory cell array and holding circuits of other memory cell arrays. A switching circuit makes two or more first selection circuits select same data and to input the same data to three or more writing circuits so that the same data is written to two or more memory cell arrays and the redundant cell array when a prescribed signal becomes active.

### CROSS-REFERENCE TO RELATED APPLICATION

This application is a continuation application of International Application PCT/JP2011/077580 filed on Nov. 29, 2011 and designated the U.S., the entire contents of which are incorporated herein by reference.

### FIELD

The embodiments discussed herein are related to a semiconductor storage device.

### BACKGROUND

Some semiconductor storage devices employ a configuration in which a plurality of memory cell arrays each being able to store data are installed and data in a prescribed bit length is divided in units of memory cell arrays and is stored. Many of this type of semiconductor storage devices include a backup memory array that is not accessed on normal occasions. This backup memory array is referred to as a redundant cell array. In a semiconductor storage device having a redundant cell array, a redundant cell array among memory cell arrays may be used instead of a memory cell array with a failure that prevents data writing or data reading. Accordingly, the provision of a redundant cell array may reduce the ratio of defective products to produced products.

A memory cell array included in a semiconductor storage device receives a test in which whether there is a defect is confirmed (redundancy determination test). This redundancy determination test is performed by performing data writing and data reading and confirming whether the written data is identical to the read data for each address. Some semiconductor storage devices have a function of performing this redundancy determination test by itself. That function is referred to as a Built-In Self Test (BIST) function.

Patent Document 1: Japanese Laid-open Patent Publication No. 2009-87513

### SUMMARY

According to an aspect of the embodiments, a semiconductor storage device including a plurality of writing circuits configured to respectively write data to a plurality of memory cell arrays and a redundant cell array, a holding circuit, which is arranged for each memory cell array, configured to hold data input as a storage target, a first selection circuit, which is arranged for each of the writing circuits of the memory cell arrays, configured to select data to be output to the writing circuits from among pieces of data input from the holding circuit of the memory cell array and holding circuits of other memory cell arrays, and a switching circuit configured to make two or more first selection circuits select same data and to input the same data to three or more writing circuits so that the same data is written to two or more memory cell arrays and the redundant cell array when a prescribed signal becomes active.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates a configuration example of a semiconductor storage device according to the present embodiment;

FIG. 2 is a timing chart representing examples of changes of the respective signals occurring when a redundancy determination test is performed in the semiconductor storage device according to the present embodiment;

FIG. 3 explains a configuration of an SRAM main body of the semiconductor storage device according to the present embodiment;

FIG. 4 illustrates a configuration of a fuse decoder provided in each input/output circuit;

FIG. 5 explains configurations of a memory cell array, a write driver circuit, and a read driver circuit;

FIG. 6 is a timing chart illustrating examples of changes in the respective signals occurring when a redundancy determination test is executed; and

FIG. 7 illustrates a configuration of an input/output circuit for a redundant cell array according to a variation example of the present embodiment.

### DESCRIPTION OF EMBODIMENTS

A redundancy determination test only tests memory cell arrays. Accordingly, for a conventional redundancy determination test, a redundant cell array having a defect is assigned instead of a memory cell array in which a defect was detected. This means that when a redundancy determination test is performed on products, a product that is treated as a defective product may be shipped.

In order to avoid the shipment of products that are treated as defective products, it is preferable that a redundancy determination test is also performed on redundant cell arrays. However, a semiconductor storage device or the BIST function included in a semiconductor storage device performs data writing or data reading for a bit length of one address (for example, 64 bits). Accordingly, when a redundancy determination test is performed on a redundant cell array in addition to a memory cell array, data writing and data reading are performed twice for one address or data writing and data reading are performed for longer data.

Performing data writing and data reading twice for one address increases a period of time needed to perform a redundancy determination test. The period of time needed to perform a redundancy determination test becomes at least twice as long. Such an increase in a period of testing time is not desirable.

When data writing and data reading are performed for data that is longer than the bit length of one address, the increase in the testing time can be avoided. However, to perform data writing and data reading for data longer than the bit length of one address, the circuit scale of the semiconductor storage device is increased. An increase in circuit scales leads to higher production cost. Accordingly, it is desirable to suppress an increase in the testing time and the production cost in view of reliably detecting semiconductor storage devices that are treated as defective products.

Hereinafter, embodiments will be explained in detail by referring to the drawings.

A redundancy determination test only tests memory cell arrays. Accordingly, for a conventional redundancy determination test, a redundant cell array having a defect is assigned instead of a memory cell array in which a defect was detected. This means that when a redundancy determination test is performed on products, a product that is treated as a defective product may be shipped.

In order to avoid the shipment of products that are treated as defective products, it is preferable that a redundancy determination test is also performed on redundant cell arrays. However, a semiconductor storage device or the BIST function included in a semiconductor storage device performs data writing or data reading for a bit length of one address (for example, 64 bits). Accordingly, when a redundancy determination test is performed on a redundant cell array in addition to a memory cell array, data writing and data reading are performed twice for one address or data writing and data reading are performed for longer data.

Performing data writing and data reading twice for one address increases a period of time needed to perform a redundancy determination test. The period of time needed to perform a redundancy determination test becomes at least twice as long. Such an increase in a period of testing time is not desirable.

When data writing and data reading are performed for data that is longer than the bit length of one address, the increase in the testing time can be avoided. However, to perform data writing and data reading for data longer than the bit length of one address, the circuit scale of the semiconductor storage device is increased. An increase in circuit scales leads to higher production cost. Accordingly, it is desirable to suppress an increase in the testing time and the production cost in view of reliably detecting semiconductor storage devices that are treated as defective products.

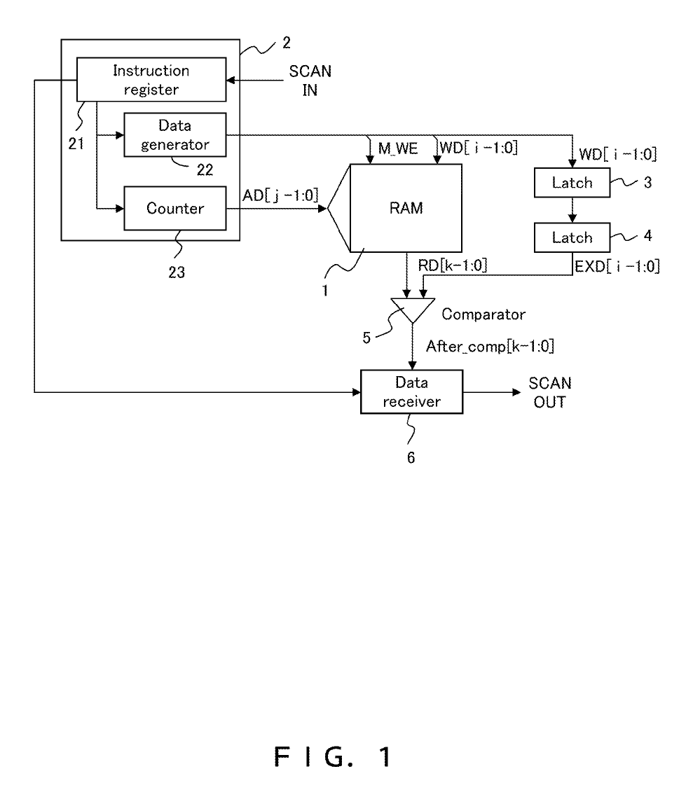

FIG. 1 illustrates a configuration example of a semiconductor storage device according to the present embodiment. The semiconductor storage device is a result of applying the present embodiment to a Static Random Access Memory (SRAM). An SRAM is implemented as one device or is included in a device such as a processor or the like. As illustrated in FIG. 1, the semiconductor storage device includes an SRAM main body 1, a pattern generator 2, two latches 3 and 4, a comparator 5, and a data receiver 6. The comparator 5 is an example of a comparison circuit.

The pattern generator 2, the two latches 3 and 4, the comparator 5, and the data receiver 6 provide the BIST function. The SRAM main body 1 is a constituent that stores data and includes a plurality of memory cell arrays and a redundant cell array as a backup of the memory cell arrays. The BIST function corresponds to a redundancy determination test for confirming defects in the plurality of memory cell arrays and the redundant cell array that constitute the SRAM main body 1. The redundancy determination test is performed sequentially on addresses that are targets for the SRAM main body 1, and is referred to as “scan” accordingly. “SCAN IN” in FIG. 1 represents an input of instruction contents for a redundancy determination test.

The pattern generator 2 includes an instruction register 21 that stores an instruction content for a redundancy determination test, a data generator 22, and a counter 23.

The instruction register 21 stores an instruction content for a redundancy determination test. The data generator 22 generates and outputs a pattern for performing a test on one address of the SRAM main body 1 in accordance with an instruction content stored in the instruction register 21. The counter 23 outputs address signal AD[j−1:0] that specifies an address. “[j−1:0]” of AD[j−1:0] represents that the number of bits of the address signal is prescribed number j. Address signal AD[j−1:0] includes a portion specifying a row address and a portion specifying a column address.

In FIG. 1, “M_WE” and “WD[i−1:0]” respectively represent a write enable signal and data for one address output from the data generator 22. “[i−1:0]” of “WD[i−1:0]” represents that the number of bits of the data is prescribed number i. Hereinafter, “Data WD” represents the entire data and “data WD”, “data WD[3:0], or the like represents particular data that is equal to or longer than one bit. When data equal to or longer than one bit is not specified, “data WD[]” is used. This applies to other pieces of data.

“EXD[i−1:0]” in FIG. 1 represents data for one address read from the latch 4. “RD[k−1:0]” in FIG. 1 represents data for one address read from the SRAM main body 1 (read data). The reason why the number of bits of that data is k is that data is written to the respective memory cell arrays and the redundant cell array at one time and data respectively read from the memory cell arrays and the redundant cell array is output in the present embodiment. Accordingly, the relationship between prescribed number i and prescribed number k satisfies k>i.

The comparator 5 associates data RD[k−1:0] from the SRAM main body 1 with data EXD[i−1:0] in units of bits and performs a comparison to confirm whether they are identical. Thereby, the comparator 5 outputs comparison result After_comp[k−1:0] that uses k (prescribed number) bits. The data receiver 6 is a constituent that accumulates/stores the comparison result After_comp[k−1:0]. Each comparison result After_comp[k−1:0] stored in the data receiver 6 is processed as a testing result of one address.

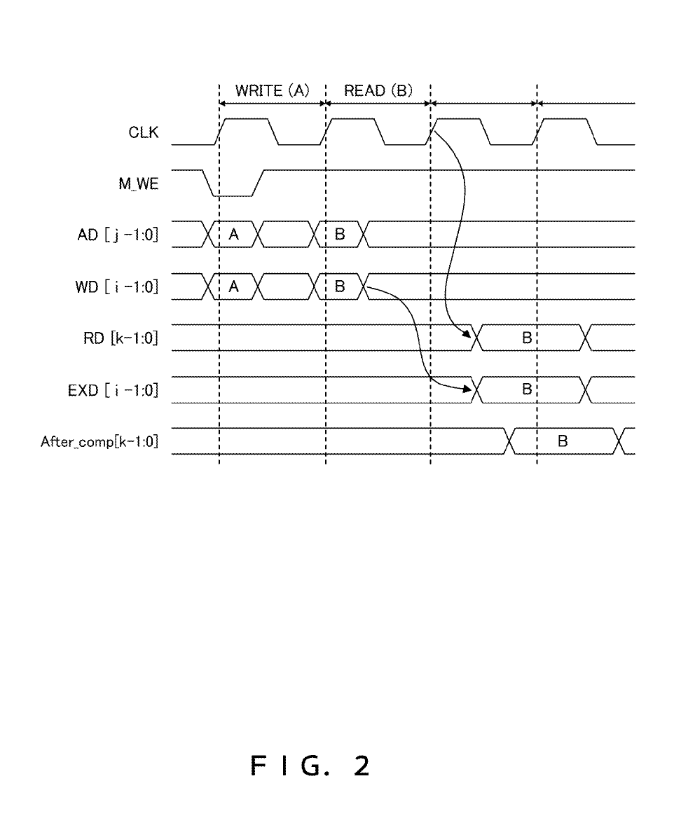

FIG. 2 is a timing chart representing examples of changes of the respective signals occurring when a redundancy determination test is performed in a semiconductor storage device according to the present embodiment. In this example, in order to express the operations of the respective members, a clock signal (CLK) that controls an access operation to the SRAM main body 1, an address signal AD[j−1:0], write enable signal M_WE, data WD[i−1:0], data RD[k−1:0], data EXD[i−1:0], and comparison result After_comp[k−1:0] are depicted as signals (pieces of data). Next, by referring to FIG. 2, the operations of the respective members for performing a redundancy determination test will be explained specifically.

“A” and “B” in FIG. 2 represent the content of data WD[i−1:0] output from the data generator 22 or address signal AD[j−1:0] corresponding to data WD[i−1:0]. Thereby, “B” in data WD[i−1:0] represents the content of data WD[i−1:0] and it is expressed that address signal AD[j−1:0] in which “B” is written is address signal AD[j−1:0] when the SRAM main body 1 is made to write data WD[i−1:0]. When the SRAM main body 1 is made to write data WD[i−1:0], the data generator 22 outputs data WD[i−1:0] that is to be written and also outputs active write enabel signal W _WE. The counter 23 outputs address signal AD[j−1:0] that specifies an address at which the SRAM main body 1 is made to store data WD[i−1:0].

The data generator 22 outputs the same data WD[i−1:0] after making write enable signal W_WE inactive and before making the write enable signal W_WE active again. Similarly, the counter 23 for example again outputs the same address signal AD[j−1:0] at the same timing as the data generator 22 outputs the same data WD[i−1:0]. By the output of address signal AD[j−1:0], data is read from the SRAM main body 1 and the SRAM main body 1 outputs data RD[k−1:0]. In this manner, data WD[i−1:0] is written to and read from the same address in the SRAM main body 1.

The reading of data RD [k−1:0] from the SRAM main body 1 is performed automatically under control of the SRAM main body 1. The reading takes a period of time for one clock signal cycle as illustrated in FIG. 2. The two latches 3 and 4 are used for adjusting (delaying) that period. Thereby, data RD[k−1:0] from the SRAM main body 1 is input to the comparator 5 almost at the same time that data EXD[i−1:0] from the latch 4 is output. Thereby, comparator 5 outputs a comparison result after_comp[k−1:0]. The purpose of again outputting the same data WD [i−1:0] from the data generator 22 is to make the latch 4 output data EXD[i−1:0].

Comparison result after_comp[k−1:0] is data representing a testing result targeting all memory cell arrays and all redundant cell arrays. A comparison result After_comp[k−1:0] such as this may be obtained by storing portions of data respectively corresponding to all memory cell arrays and all redundant cell arrays with one time of writing of data WD[i−1:0] and by reading data from all of them with one time of reading. Thereby, a redundancy determination test for one address can be performed for basically the same period of time as that used by the conventional redundancy determination test, which only targets memory cell arrays. Thereby, the present embodiment avoids an extension of a period of time to perform a redundancy determination test, which would be caused by targeting a redundant cell array.

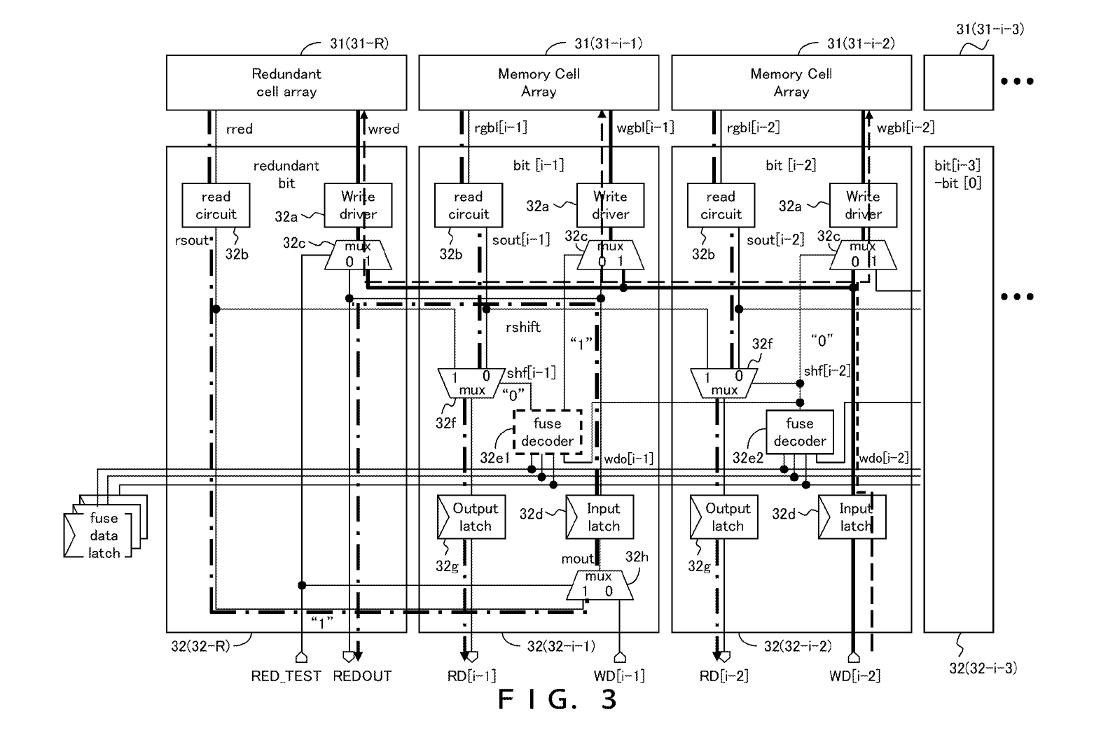

FIG. 3 explains a configuration of an SRAM main body. As illustrated in FIG. 3, the SRAM main body 1 includes i memory cell arrays 31 (31-0 through 31-i−1), a redundant cell array 31 (31-R), and input/output circuits 32 (32-0 through 32-i−1 and 32-R) that are provided for the memory cell arrays 31 and the redundant cell array 31-R, respectively. While the number of the redundant cell array 31-R is one, the number of the redundant cell array 31-R may be two or more. Because the number of the redundant cell array 31-R is one, the relationship between prescribed number k and prescribed number i satisfies k=i+1.

In this example, “31” is used as a numeral for both a memory cell array and a redundant cell array. This is because memory cell arrays and redundant cell arrays have the same configuration. Each of the memory cell arrays 31 and the redundant cell array 31-R store data of one bit for each address. That is why the number of memory cell arrays 31 is i.

In FIG. 3, “bit[i−3]−bit[xx0xx]”, “bit[i−2]”, and “bit[i−1]” in the respective input/output circuits 32 represent the positions of inherently associated data of one bit among pieces of data of i bits. “Redundant bit” represents data of one bit to which the memory cell array 31 corresponds.

The input/output circuits 32-0 through 32-i−2, the input/output circuit 32-i−1, and the input/output circuit 32-R have different configurations. Thus, separate explanations will be given for the configurations of the input/output circuit 32-i−2, the input/output circuit 32-i−1, and the input/output circuit 32-R.

The input/output circuit 32-i−2 inputs data WD[i−2], which is one-bit data in data WD[i−1:0], and stores the data in a latch 32d. The latch 32d is an example of a holding circuit. Data WD[i−2] stored in the latch 32d is input as data wdo[i−2] to terminal 0 of a multiplexer (“mux” in FIG. 3) 32c. The multiplexer 32c is an example of a first selection circuit. To terminal 1 of the multiplexer 32c, data wdo[i−3] is input from the latch 32d of the input/output circuit 32-i−3. The multiplexer 32c selects one of data wdo[i−2] and wdo[i−3], input respectively to terminal 0 and terminal 1, in accordance with control signal shf[i−2] output from a fuse decoder 32e2, and outputs the selected data to a write driver circuit 32a. The fuse decoder 32e2 is an example of a switching circuit. The write driver circuit 32a writes data input from the multiplexer 32c as data wgbl[i−2] to the memory cell array 31-i−2.

“[i−2]” in “shf[i−2]” above is a symbol string representing the position (digit) of one bit associated in data of i bits. Unless otherwise stated, the symbol string representing the position is omitted, and it is referred to as “control shf”. This applies to other symbols.

The multiplexer 32c selects data wdo[i−2] input to terminal 0 when the value (logical value) of control signal shf[i−2] is zero and selects wdo[i−3] input to terminal 1 when the value is one. Thereby, data wgbl[i−2] to be written to the write driver circuit 32a may be selected from among data WD[i−2] and WD[i−3] input to the input/output circuits 32-i−2 and the input/output circuit 32-i−3. Accordingly, when for example it is confirmed that there is a defect in the memory cell array 31-i−3, data WD[i−3] input to the input/output circuit 32-i−3 may be written as data wgbl[i−2] from the adjacent input/output circuit 32-i−2 to the memory cell array 31-i−2. In such a case, data WD [i−2] input to the input/output circuit 32-i−2 is written as data wgbl[i−1] from the input/output circuit 32-i−1 to the memory cell array 31-i−1. Thereby, the SRAM main body 1 may prohibit accesses to the memory cell array 31 in which the existence of a defect has been confirmed and may use other memory cell arrays 31 or the redundant cell array 31-R instead of that memory cell array 31.

The reading of data from the memory cell array 31-i−2 is performed by a read circuit 32b. Data rgbl[i−2] read by the read circuit 32b is input to terminal 0 of a multiplexer 32f as data sout[i−2]. The multiplexer 32f is an example of a second selection circuit. To terminal 1 of a multiplexer 32f, data rgbl[i−1] read by the read circuit 32b of the input/output circuit 32-i−1 is input as data sout[i−1].

Similarly to the multiplexer 32c, the multiplexer 32f selects one of data sout[i−2] or data sout[i−1] input to terminal 0 or terminal 1 in accordance with the value of control signal shf[i−2] output from the fuse decoder 32e2, and outputs the selected data. Because the selection control is performed by control signal shf[i−2], which is the signal that controls the multiplexer 32, when data WD[i−2] input to the input/output circuit 32-i−2 has been written to the memory cell array 31-i−1, the multiplexer 32f selects data WD[i−2] (sout[i−1]) read as data rgbl [i−1] from the memory cell array 31-i−1. Data selected/output by the multiplexer 32f is stored in the latch 32g and is output to the outside of the SRAM main body 1 as data RD[i−2].

The main configuration of the input/output circuit 32-i−1 is the same as that of the input/output circuit 32-i−2. Accordingly, the same constituents as those in the input/output circuit 32-i−2 are denoted by the same numerals. Therefore, explanations will be given by paying attention only to portions different from the input/output circuit 32-i−2.

In the input/output circuit 32-i−1, a multiplexer 32h is provided between the latch 32d and the input terminal. The input terminal is connected to terminal 0 of the multiplexer 32h, and terminal 1 of the multiplexer 32h is connected to the read circuit 32b of the input/output circuit 32-R. Thereby, the input/output circuit 32-i−1 may store, in the latch 32d, data mout, which is data selected by the multiplexer 32h from among input data WD[i−1], and data rsout (data rred) read from the redundant cell array 31-R.

As a control signal for performing the selection control of the multiplexer 32h, signal RED_TEST, which is input from the input terminal of the input/output circuit 32-R, is input. That input terminal is a terminal provided for performing a redundancy determination test. The value of signal RED_TEST, input to that input terminal varies depending upon whether a redundancy determination test is being executed. That signal is referred to as a “test signal” hereinafter.

Test signal RED_TEST is in an active state during the execution of a redundancy determination test and the value thereof is one. Accordingly, the multiplexer 32h does not select data WD[i−1] input to the input terminal during the execution of a redundancy determination test.

It is when data is written to the memory cell array 31-i−1 that data WD[i−1] is input to an input terminal. At this moment, data rsout is not input to terminal 1 of the multiplexer 32h from the read circuit 32b of the input/output circuit 32-R. Accordingly, when data is written, data that is to be written to the memory cell array 31-i−1 is not stored in latch 32d. Accordingly, a fuse decoder 32e1, which is different from that of the input/output circuit 32-i−2, is used for the input/output circuit 32-i−1.

The fuse decoder 32e1 outputs two types of control signals i.e., rshift and shf[i−1]. Control signal rshift is output to the multiplexer 32c and control signal shf[i−1] is output to the multiplexer 32f.

The input/output circuit 32-R includes a write driver circuit 32a, a read circuit 32b, and a multiplexer 32c similarly to other input/output circuits 32-i−2 and 32-i−1. As a terminal, it includes an output terminal for data REDOUT in addition to an input terminal for test signal RED_TEST above.

Terminal 1 of the multiplexer 32c of the input/output circuit 32-R is connected to the latch 32d of the input/output circuit 32-i−2 as described above, and terminal 0 of the multiplexer 32c is connected to the output terminal (denoted by “REDOUT” in FIG. 3) of the input/output circuit 32-R and the latch 32d of the input/output circuit 32-i−2. It is connected to an input terminal for test signal RED_TEST so that control signals are input. Thereby, the write driver circuit 32a of the input/output circuit 32-R writes data wdo[i−2] or wdo[i−1] to the redundant cell array 31-R as data wred.

The read circuit 32b of the input/output circuit 32-R is connected to terminal 1 of the multiplexer 32f of the input/output circuit 32-i−1 in addition to terminal 1 of the multiplexer 32h of the input/output circuit 32-i−1. In a situation where a redundancy determination test is not being executed, data rred read by the read circuit 32b is output via the multiplexer 32f of the input/output circuit 32-i−1 as data rsout. In a situation where a redundancy determination test is being executed, data rsout from the read circuit 32b is output via the multiplexer 32h of the input/output circuit 32-i−1.

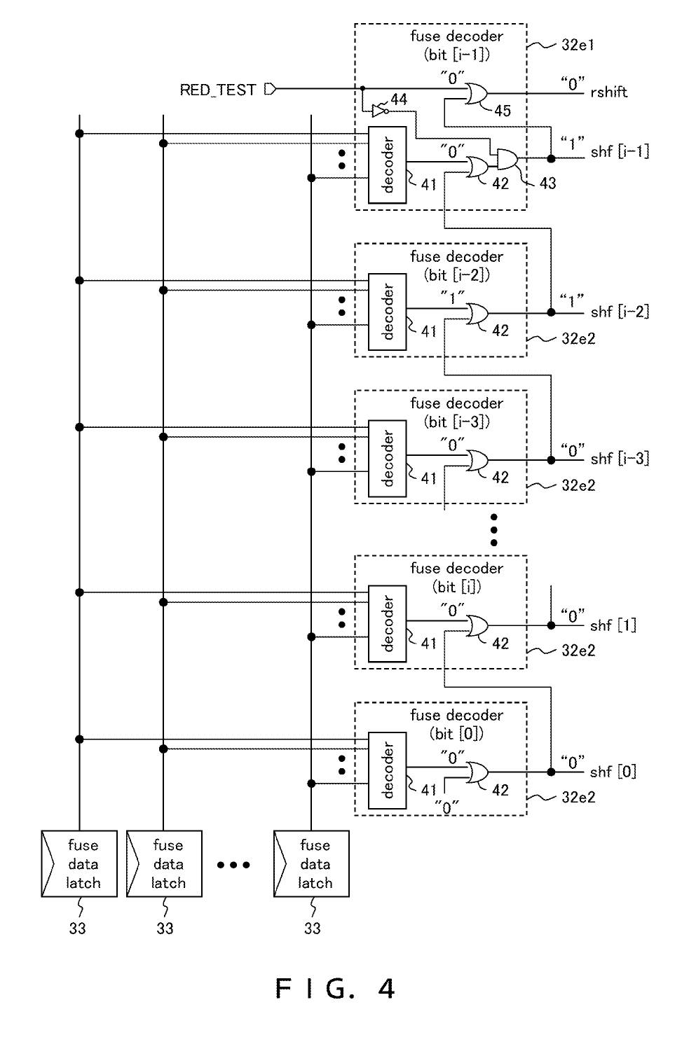

FIG. 4 illustrates a configuration of a fuse decoder provided in each input/output circuit. In FIG. 4, “bit[xx0xx]”, “bit[xx1xx]”, etc. in the respective decoders 32e1 and 32e2 represent the positions (digits) of associated data of one bit among data of i bits similarly to FIG. 3.

Each of the fuse decoders 32e2 used in the respective input/output circuits 32-0 through 32-i−2 and the fuse decoder 32e1 used in the input/output circuit 32-i−1 includes a decoder 41, and each of the decoders 41 is connected to a plurality of latches 33. The plurality of the latches 33 are used for holding fuse data that represents the memory cell array 31 for which accesses are prohibited. Thereby, the number of the latches 33 is equal to or greater than a number of bits that can express number i, which is the number of the memory cell array 31.

Each decoder 41 outputs a signal of “1” when for example the value represented by fuse data held by the plurality of latches 33 is identical to the value representing the position of an associated bit. Thereby, when for example the value represented by fuse data is “0”, the decoder 41 of the fuse decoder 32e2 denoted by “bit [xx0xx] ” outputs a signal of “1”. When for example the value represented by fuse data is i−2, the decoder 41 of the fuse decoder 32e2 denoted by “bit[i−2]” outputs a signal of “1”.

In each fuse decoder 32e2, an output signal of the decoder 41 is input to an OR gate 42. The OR gate 42 outputs the logical sum of the input signal and control signal shf of the fuse decoder 32e2 having an associated position (digit) that is lower by one digit. That logical sum is output as control signal shf of that fuse decoder 32e2. The OR gate 42 of the fuse decoder 32e2 having an associated bit position that is the lowest outputs the logical sum of the output signal of the decoder 41 and the signal having the value of “0” because the fuse decoder 32e2 to which control signal shf is to be input does not exist.

Accordingly, when control signal shf of one of the fuse decoders 32e2 has become 1, all of the fuse decoders 32e2 to which bits higher than that fuse decoder 32e2 are associated output control signals shf of 1. As a result of this, the input/output circuit 32 including the fuse decoder 32e2 having the lowest associated bit among the fuse decoders 32e2 whose control signals shf have become 1 halts accesses to the associated memory cell array 31. The input/output circuits 32 including the other fuse decoders 32e2 having control signals shf that have become 1 use, for writing, data input from the input/output circuit 32 having the associated bit that is one bit lower, and outputs data input from the input/output circuit 32 having the associated bit that is one bit higher.

In the fuse decoder 32e1 of the input/output circuit 32-i−1, the logical sum of the OR gate 42 and an output signal of an inverter 44 is input to an AND gate 43, and the logical product of the AND gate 43 is output as control signal shf [i−1] . The inverter 44 outputs the negative of test signal RED_TEST. Accordingly, when test signal RED_TEST is active, i.e., when the value of the test signal is 1, the value of control signal shf[i−1] is always zero.

A logical product output from the AND gate 43 is input to the OR gate 45. The OR gate 45 outputs the logical sum of the logical product and test signal RED_TEST. The logical sum is output as control signal rshift. Therefore, the value of control signal rshift becomes 1 when test signal RED_TEST is active. When test signal RED_TEST is inactive, the value of control signal rshift is always identical to the value of a logical product output from the AND gate 43, i.e., the value of control signal shf[i−1]. Thereby, in a situation where a redundancy determination test is not executed, the fuse decoder 32e1 and the fuse decoder 32e2 operate in a similar manner.

Operations in the above configuration will be explained. The input/output circuits 32-0 through 32-i−2 have the same configuration, and the input/output circuits 32-i−1 and the input/output circuit 32-R have different configurations. Thus, explanations will be given for the operations by paying attention to the input/output circuit 32-i−2, the input/output circuit 32-i−1, and the input/output circuit 32-R.

First, a case when a redundancy determination test is not executed, i.e., when test signal RED_TEST input to the input terminal of the input/output circuit 32-R is inactive, will be explained.

When data is written, the latch 32d of the input/output circuit 32-i−2 takes in data WD[i−2] input to the input terminal, and holds it. When the value of control signal shf[i−2] output from the fuse decoder 32e2 of the input/output circuit 32-i−2 is zero, the multiplexer 32c selects, via terminal 0, data wdo[i−2] held by the latch 32d and outputs it. Thereby, the write driver circuit 32a writes, in the memory cell array 31-i−2 and as data wgbl[i−2], data wdo[i−2] from the latch 32d of the input/output circuit 32-i−2.

The multiplexer 32c of the input/output circuit 32-i−1 outputs to the write driver circuit 32a data wdo[i−1] from the latch 32d when the value of control signal rshift output from the fuse decoder 32e1 is zero. Thereby, the write driver circuit 32a writes data wdo[i−1] to the memory cell array 31-i−1 as data wgbl[i−1]. At this moment, a test signal input to input terminal RED_TEST is inactive. Accordingly, the input/output circuit 32-R does not write data wred. The value of control signal shf[i−1] is zero, which is the same as that of control signal rshift.

In a situation where control signals rshift, shf[i−1], and shf[i−2] are output, pieces of data rgbl[i−1] and rgbl[i−2] read by the input/output circuits 32-i−1 and 32-i−2 are output as they are. Namely, pieces of data rgbl[i−1] and rgbl[i−2] are output via the multiplexer 32f and the latch 32g from the respective output terminals as pieces of data RD[i−1] and RD[i−2]. The input/output circuit 32-R does not read data rred.

When the value of control signal shf[i−2] output from the fuse decoder 32e2 of the input/output circuit 32-i−2 is 1, data is written in the following manner. In such a case, the multiplexer 32c selects and outputs data wdo[i−3] from the latch 32d of the input/output circuit 32-i−3 via terminal 1. Thereby, the write driver circuit 32a writes, to the memory cell array 31-i−2 and as data wgbl[i−2], data wdo[i−3] from the latch 32d of the input/output circuit 32-i−3. Similarly, the write driver circuit 32a of the input/output circuit 32-i−1 writes, to the input/output circuit 32-i−1 and as data wgbl[i−1], data wdo[i−2] from the latch 32d of the input/output circuit 32-i−2. The write driver circuit 32a of the input/output circuit 32-R writes, to the redundant cell array 31-R and as data wred, data wdo[i−1] from the latch 32d of the input/output circuit 32-i−1. As a result of this, in the reading of data, data rred read from the redundant cell array 31-R is output as data RD[i−1] from the output terminal of the input/output circuit 32-i−1. Data rgbl[i−1] read from the memory cell array 31-i−1 is output from the output terminal of the input/output circuit 32-i−2 as data RD[i−2].

Next, explanations will be given for operations in a case where a redundancy determination test is executed, i.e., a case where a test signal RED_TEST is active.

When a redundancy determination test is executed, the value of control signal shf[i−2] output from the fuse decoder 32e2 of the input/output circuit 32-i−2 is assumed to be zero, and the value of control signal rshift output from the fuse decoder 32e1 of the input/output circuit 32-i−1 is assumed to be 1. Fuse data for outputting such control signals is stored in the plurality of latches 33.

Even in a case where data is written under the above described situation, the latch 32d of the input/output circuit 32-i−2 takes in data WD[i−2] input to the input terminal and stores it. Because the value of control signal shf[i−2] output from the fuse decoder 32e2 of the input/output circuit 32-i−2 is zero, the multiplexer 32c selects and outputs, via terminal 0, data wdo[i−2] from the latch 32d. Thereby, the write driver circuit 32a writes data wdo[i−2] to the memory cell array 31-i−2 as data wgbl[i−2]. Because the value of control signal rshift output from the fuse decoder 32e1 is 1, the write driver circuit 32a of the input/output circuit 32-i−1 writes data wdo[i−2] from the latch 32d of the input/output circuit 32-i−2 to the memory cell array 31-i−1 as data wgbl[i−1]. The write driver circuit 32a of the input/output circuit 32-R writes data wdo[i−2], as data wred, from the latch 32d of the input/output circuit 32-i−2 to the redundant cell array 31-R from the latch 32d of the input/output circuit 32-i−2 because control signal RED_TEST is active. As a result of this, as represented by the dashed line arrows in FIG. 3, data WD[i−2] input to the input/output circuit 32-i−2 is input to the memory cell arrays 31-R, 31-i−1, and 31-i−2.

The values of control signals shf[i−1] and shf[i−2] input to the multiplexers 32f of the input/output circuits 32-i−1 and 32-i−2 are both zero. Accordingly, in the reading of data, the input/output circuits 32-i−1 and 32-i−2 output, as pieces of data RD [i−1] and RD [i−2] , pieces of data rgbl[i−1] and rgbl[i−2] respectively read from the memory cell arrays 31-i−1 and 31-i−2. Data rred read from the redundant cell array 31-R by the read circuit 32b of the input/output circuit 32-R is input to the latch 32d as data mout from the multiplexer 32h of the input/output circuit 32-i−1 because transition RED_TEST is active. Thereby, data rred read from the redundant cell array 31-R is held by the latch 32d and thereafter is output as data REDOUT from the output terminal of the input/output circuit 32-R. As a result of this, as represented by the dashed-dotted line arrows in FIG. 3, data read from the memory cell arrays 31-R, 31-i−1, and 31-i−2 is output. Data REDOUT is output as data RD[k−1] from the SRAM main body 1.

In the above described method, when a redundancy determination test is executed in the present embodiment, data is written to all of the memory cell arrays 31 and the redundant cell array 31-R and all the written data is read at one time. The data read from the redundant cell array 31-R is output later than the data read from the other memory cell arrays 31. However, as will be described later in detail, the data read from the redundant cell array 31-R is output from the SRAM main body 1 together with the data read from the other memory cell arrays 31. As a result of this, the comparator 5 outputs comparison result after_comp[k−1:0], which is data representing the comparison result for k minutes (k is a prescribed number). Thereby, in the present embodiment, executing a redundancy determination test is done for the same period of time as used by the conventional redundancy determination test, which only targets all of the memory cell arrays 31. The comparator 5 compares all pieces of three-bit data RD[k−1] through RD[k−3] among data RD[k−1:0] from the SRAM main body 1 with one-bit data EXD[i−2].

The writing of data to all of the memory cell arrays 31 and the redundant cell array 31-R can be performed by writing the same data to the total three memory cell arrays 31 and by the SRAM main body 1 inputting i-bit data WD[i−1:0]. Thereby, it is not necessary to respond to an input of data that is longer than the bit length of one address, making it possible to reduce an increase in the circuit scale or the production cost of semiconductor storage devices. Also, the output of data rred read from the redundant cell array 31-R is performed by using the latch 32d, which is a constituent of the input/output circuit 32-i−1. Thereby, that latch is used commonly for two purposes, i.e., the purpose of holding data WD[i−1] input to the input/output circuit 32-i−1 for a case when a redundancy determination test is not executed and the purpose of holding data REDOUT output from the input/output circuit 32-R for a case when a redundancy determination test is executed. Accordingly, the configuration of the input/output circuit 32-R is simpler than that of the input/output circuit 32-i−2 while making it possible to read and write data when a redundancy determination test is executed. Thereby, according to the present embodiment, an increase in the circuit (hardware) scale of semiconductor storage devices, i.e., an increase in production costs of semiconductor storage devices, is suppressed further while making it possible to execute a redundancy determination test targeting all of the memory cell arrays 31 and the redundant cell array 31-R at one time.

In the present embodiment, it is made possible to perform data writing and data reading targeting all of the memory cell arrays 31 and the redundant cell array 31-R at one time respectively, however, it is also possible to make it possible to only perform either data writing or data reading at one time. Even in this configuration, it is possible to execute a redundancy determination test in a shorter period of time than a case where data writing and data reading are performed separately.

Also, in the present embodiment, the function of using the redundant cell array 31-R upon detection of a defect in the memory cell array 31 is utilized so that data can be written to all of the memory cell arrays 31 and the redundant cell array 31-R at one time. This is to minimize an increase in the circuit (hardware) scale of semiconductor storage devices, i.e., an increase in production costs of semiconductor storage devices. When a further increase in the circuit scale of semiconductor storage devices can be tolerated, other methods may be used. For example, when a latch for holding data to be output is provided to the input/output circuit 32-R, it is possible to omit the multiplexer 32h of the input/output circuit 32-i−1 and the multiplexer 32c of the 32-R. In such a case, the fuse decoder 32e2 may be used for the input/output circuit 32-i−1.

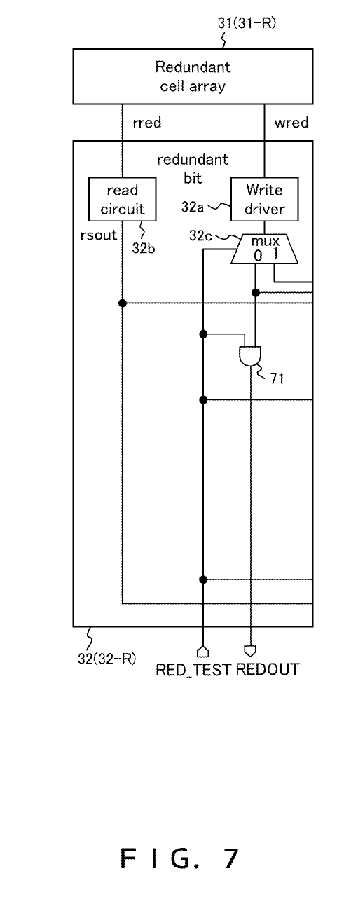

The output terminal of the input/output circuit 32-R is connected to the latch 32d of the input/output circuit 32-i−1, and accordingly the output terminal outputs data REDOUT corresponding to data wdo[i−1] from the latch 32d in normal operations, in which a redundancy determination test is not executed. Accordingly, it is also possible as illustrated in FIG. 7 to provide an AND gate 71 that outputs, as data REDOUT, the logical product of data wdo[i−1] from the latch 32d of the input/output circuit 32-i−1 and test signal RED_TEST so that output data REDOUT is controlled. When the AND gate 71 such as the above is provided, it is possible to continuously keep the value of output data REDOUT 0 (zero) in normal operations. This leads to further reduction in power consumption.

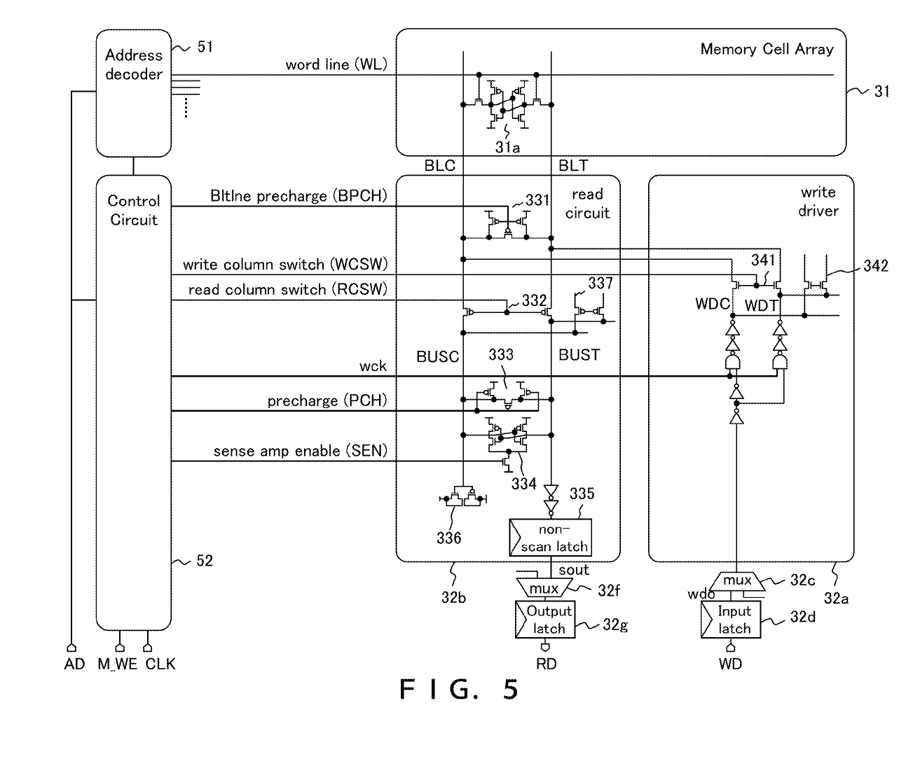

FIG. 5 explains configurations of a memory cell array, a write driver circuit, and a read driver circuit. Next, by referring to FIG. 5, explanations will be given for the memory cell arrays 31, the write driver circuit 32a, and the read circuit 32b in more detail.

Accesses to the memory cell array 31 are controlled by a control circuit 52. To the control circuit 52, a clock signal (CLK) illustrated in FIG. 2, address signal AD[j−1:0] (denoted by “AD” in FIG. 5), and write enable signal M_WE are input. Test signal RED_TEST and setting information are also input to the control circuit 52, although they are not illustrated in the figures. Setting information includes information representing for example the memory cell array 31 for which prohibiting access is preferably. Thereby, the control circuit 52 includes a function of generating fuse data from setting information and storing it in the latch 33, and selects the memory cell array 31 for which access is allowed in accordance with test signal RED_TEST and fuse data from among the memory cell arrays 31.

An address decoder 51 inputs address signal AD, and makes active at least one word line WL in accordance with input address signal AD. By making one word line WL active, access to the write driver circuit 32a having a row address represented by address signal AD is allowed from among the memory cell arrays 31.

The memory cell array 31 includes one word line WL and a memory cell 31a for each crossing point between a pair of local bit lines BLC and BLT. Selection of the memory cell 31a having a row address represented by address signal AD is made by selection of a pair of local bit lines BLC and BLT. The memory cell 31a is a flip flop circuit including four N-type channel MOS (Metal-Oxide-Semiconductor) FETs (Field Effect Transistors) (referred to as NMOS transistors hereinafter) and two P-type channel MOS FETs (referred to as PMOS transistors hereinafter).

A pair of local bit lines BLC and BLT are connected to a pair of global bit lines BUSC and BUST. To a pair of global bit lines BUSC and BUST, all local bit lines BLC and BLT of the memory cell 31a having a corresponding column address are connected.

To each pair of global bit lines BUSC and BUST, a bit line precharge circuit 331, a read column switch circuit 332, a precharge circuit 333, and a sense amplification circuit 334 are connected.

The bit line precharge circuit 331 is a circuit that performs precharging so that the logical values of both local bit lines BLC and BLT become 1. In this example, the bit line precharge circuit 331 includes three PMOS transistors. Precharging by the bit line precharge circuit 331 is executed when a BPCH (Bitline precharge) signal has become active, i.e., when the signal level thereof has become L (low).

The read column switch circuit 332 is a circuit that controls reading of data from the memory cell 31a, and includes two PMOS transistors arranged for switching in global bit lines BUSC and BUST. The reading of data is enabled when an RCSW (read column switch) signal input to the gate of each PMOS transistor has become active, i.e., when the signal level thereof has become L.

The precharge circuit 333 is a circuit that performs precharging so that the logical values of both of global bit lines BUSC and BUST become 1. Similarly to the bit line precharge circuit 331, the precharge circuit 333 includes three PMOS transistors. Precharging by the precharge circuit 333 is enabled when a PCH (precharge) signal has become active, i.e., when the signal level thereof has become L.

The sense amplification circuit 334 is a circuit that amplifies voltage levels of global bit lines BUSC and BUST, and includes three NMOS transistors and two PMOS transistors. Amplification of voltage levels by the sense amplification circuit 334 is performed when an SEN (sense amp enable) signal has become active, i.e., when the signal level thereof has become H (high).

To global bit line BUST, a latch 335 is connected via two invertors. The logical value of global bit line BUST when a SEN signal held by the latch 335 has become active is output as data sout read by the read circuit 32b.

In addition to the above, circuits 336 and 337 are provided to the read circuit 32b. The circuit 336 connected to the global bit line BUSC is a dummy circuit added for equalizing the input loads on the sense amplifier. The circuit 337 is a read column switch circuit for other columns.

The write driver circuit 32a includes a pair of write data lines WDC and WDT for each pair of global bit lines BUSC and BUST . Thereby, the write driver circuit 32a can write data to the memory cell array 31 via the read circuit 32b.

To a pair of write data lines WDC and WDT, a write column switch circuit 341 that controls writing of data to the memory cell 31a is provided. The write column switch circuit 341 includes two NMOS transistors arranged for each of the write data liens WDC and WDT. Writing of data is enabled when a WCSW (write column switch) signal input to the gate of each NMOS transistor has become active, i.e., when the signal level thereof has become H. To a pair of write data lines WDC and WDT, a write column switch circuit 342 for other columns is connected.

Data input to the write driver circuit 32a is output to two NAND gates via one or two inverters. Each NAND gate outputs to an inverter the negative logical product of the input data and a pulsed clock signal WCK output from the control circuit 52. To write data line WDC, the negative logical product of the NAND gate that inputs data via two inverters is output via two inverters. To write data line WDT, the negative logical product of the NAND gate that inputs data via one inverter is output via two inverters.

When the control circuit 52 is to write data, the control circuit 52 determines, from address signal AD, data lines WDC and WDT and local bit lines BLC and BLT to be used for the data writing in the write driver circuit 32a in each of the input/output circuits 32. Test signal RED_TEST and fuse data are used for determining the write driver circuit 32a to be used for the data writing in the respective input/output circuits 32. When data is to be read, the control circuit 52 determines, from address signal AD, local bit lines BLC and BLT and global bit lines BUSC and BUST to be used for the data reading in the read circuit 32b in each of the input/output circuits 32. Test signal RED_TEST and fuse data are used for determining the read circuit 32b used for reading data in the respective input/output circuits 32. The control circuit 52 controls data writing or data reading on the basis of whether write enable signal M_WE is active when address signal AD is active when address signal AD is input.

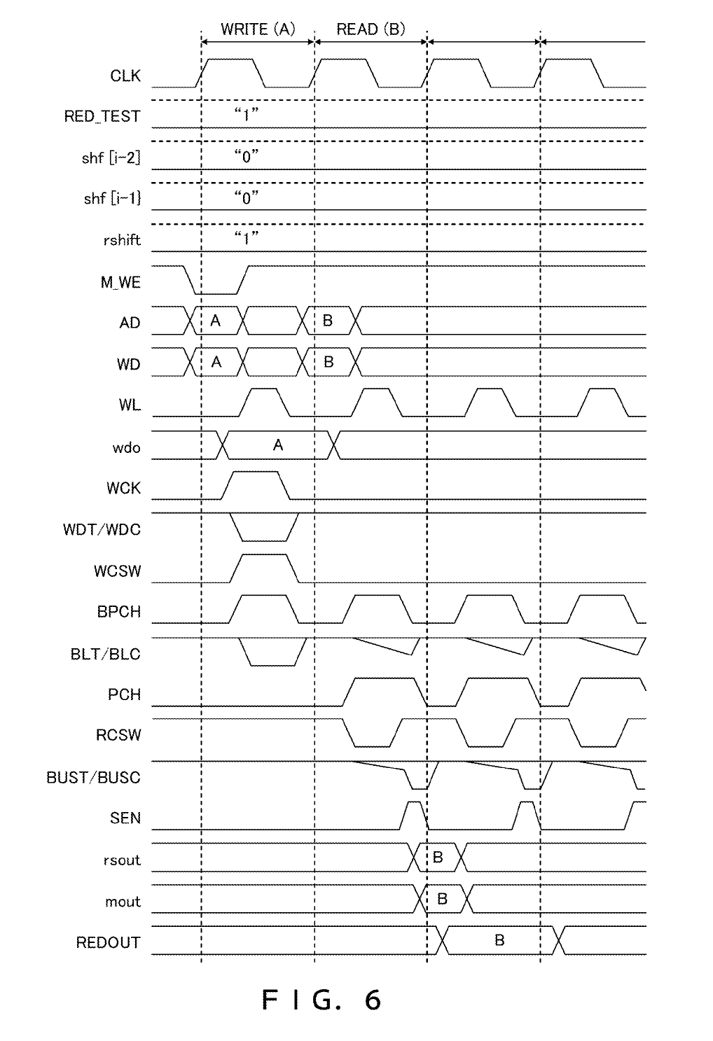

FIG. 6 is a timing chart illustrating examples of changes in the respective signals occurring when a redundancy determination test is executed. Next, operations of the respective members will be explained in detail by referring to FIG. 6.

In FIG. 6, symbol strings representing signals are denoted by CLK, RED_TEST, shf[i−2], shf[i−1], rshift, M_WE, AD, WD, WL, wdo, WCK, WDT/WDC, WCSW, BPCH, BLT/BLC, PCH, RCSW, BUST/BUSC, SEN, rsout, mout, and REDOUT. These symbol strings represent the signals described below.

CLK is a clock signal input to the control circuit 52. RED_TEST is a test signal. sfh[i−2] is a control signal output by the fuse decoder 32e2 of the input/output circuit 32-i−2. rshift is a control signal output by the fuse decoder 32e1 of the input/output circuit 32-i−1. When the execution of a redundancy determination test is assumed, the logical values of test signal RED_TEST and control signal rshift are both 1 and the logical values of control signals shf[i−1] and shf[i−2] are both zero.

M_WE is a write enable signal. AD is an address signal output by the pattern generator 2. WD is data output by the pattern generator 2. WL is a voltage level of a word line. wdo is data output by for example the latch 32d of the input/output circuit 32-i−2. WCK is a pulsed clock signal. WDT/WDC is a voltage level of each data write line. WCSW is a WCSW signal. BPCH is a BPCH signal. BLT/BLC is a voltage level of each local bit line. PCH is a PCH signal. RCSW is an RCSW signal. BUST/BUSC is a voltage level of each global bit line. SEN is a SEN signal. rsout is data output by the read circuit 32b of the input/output circuit 32-R. mout is data output by the multiplexer 32h of the input/output circuit 32-i−1. REDOUT is data output from the output terminal of the input/output circuit 32-R.

Among the above respective signals, L means “active” for a BPCH signal, a PCH signal, and an RCSW signal. For the other signals, H is used to mean H as a voltage level or “1” as a logical value.

Also, in FIG. 6, “A” and “B” represent, similarly in FIG. 2, the content of data WD[i−1:0] output by the data generator 22 or address signal AD[j−1:0] corresponding to data WD[i−1:0], respectively. “WRITE(A)” and “READ(B)” situated along arrows respectively represent a period of time for the control circuit 52 to write data WD of the content of A and a period of time for the control circuit 52 to read data WD of the content of B.

First, operations of a case when data WD is written will be explained.

When data is to be written, the pattern generator 2 outputs active write enable signal W_WE, data WD (data of the content of A in this example), and address signal AD. In the SRAM main body 1, by receiving data WD, the latch 32d of each of the input/output circuits 32-0 through 32-i−2 takes in the data and holds the data, and outputs pieces of data wdo through wdo[i−2]. The address decoder 51 inputs address signal AD upon the rising of the next clock signal and makes one word line WL active, i.e., makes the voltage level H. The control circuit 52 starts write control upon the rising of the next clock signal, and makes pulsed clock signals WCK and BPCH active. The voltage levels of each of write data lines WDC and WDT change in accordance with input data wdo. As a result of this, data (data wdo) represented by voltage levels of write data lines WDC and WDT is written to the memory cell 31a through connected local bit lines BLC and BLT.

Next, operations in a case when data is read from the memory cell array 31 are explained.

When data is read, the pattern generator 2 outputs data WD (data of the content of B in this example) and address signal AD. The address decoder 51 of the SRAM main body 1 inputs address signal AD and makes one word line WL active, i.e., changes the voltage to level H upon the rising of the next clock signal. The control circuit 52 starts reading control upon the rising of the next clock signal, makes a BPCH signal and a PCH signal inactive so as to cancel the precharge, and makes respective RCSW signals active. Each of the local bit lines BLC and BLT is precharged by the activation of the BPCH signal, and the voltage level thereof changes. Similarly, each of the global bit lines BUSC and BUST is also precharged by the activation of the PCH signal and the voltage level thereof changes.

The control circuit 52 makes a SEN signal active with a PCH signal being inactive. By making a SEN signal active, the voltage levels of the respective global bit lines BUSC and BUST are amplified by the sense amplification circuit 334. In the input/output circuit 32-R, the voltage level of global bit line BUST that has received the amplification is output from the read circuit 32b as data rsout via the latch 335.

rsout output from the read circuit 32b is thereafter output as mout from the multiplexer 32h of the input/output circuit 32-i−1. Data mout is held by the latch 32d of the input/output circuit 32-i−1 and is output as data REDOUT from the output terminal of the input/output circuit 32-R.

Because of the situation as described above, data

REDOUT is output from the SRAM main body 1 as one-bit data of data RD[k−1:0] represented in FIG. 2. Pieces of data from other input/output circuits 32-0 through 32-i−1 are output at timings earlier than that of data REDOUT. Thereby, data

RD[k−1:0] is generated in a form wherein data REDOUT is added to data RD[k−2:0] as data RD[k−1].

According to an aspect, an increase in a period of time for a redundancy determination test or in production cost is suppressed. Also, according to the present embodiment, a semiconductor storage device has a BIST function; however, a semiconductor storage device to which the present embodiment is applied does not have to have a BIST function. Thereby, the present embodiment may be applied to a device for performing a redundancy determination test and a semiconductor storage device that is a target of that redundancy determination test, respectively.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor storage device comprising:
a plurality of memory cell arrays;
a redundant cell array which is a backup memory cell array of the memory cell arrays;
a plurality of writing circuits configured to respectively write data to the plurality of memory cell arrays and the redundant cell array;
a holding circuit, which is arranged for each memory cell array, configured to hold data input as a storage target;
a first selection circuit, which is arranged for each of the writing circuits of the memory cell arrays, configured to select data to be output to the writing circuits from among pieces of data input from the holding circuit of the memory cell array and holding circuits of other memory cell arrays; and
a switching circuit configured to make two or more first selection circuits select same data and to input the same data to three or more writing circuits so that the same data is written to two or more memory cell arrays and the redundant cell array when a prescribed signal becomes active.

2. The semiconductor storage device according to claim 1, further comprising:
a plurality of reading circuits configured to respectively read data from the plurality of memory cell arrays and the redundant cell array;
a second selection circuit, which is arranged for each of the reading circuits of the memory cell arrays, configured to select and output one of pieces of data respectively read from the reading circuits and reading circuits of the other memory cell arrays or the redundant cell array; and
an output circuit configured to output data read from the reading circuit of the redundant cell array separately from data outputted from the respective reading circuits of the plurality of memory cell arrays via the second selection circuits when the prescribed signal becomes active.

3. The semiconductor storage device according to claim 1, further comprising
a comparison circuit configured to perform comparison to confirm whether pieces of data respectively read from the plurality of memory cell arrays and the redundant cell array are appropriate by using data stored in the plurality of memory cell arrays when the prescribed signal becomes active.

4. The semiconductor storage device according to claim 2, wherein
the output circuit outputs data read from the redundant cell array by using a holding circuit of a memory cell array to which the same data as that of the redundant cell array is written when the prescribed signal becomes active.

5. A testing method comprising:
writing data respectively to a plurality of memory cell arrays provided in the semiconductor storage device and the redundant cell array that is a backup memory cell array of the memory cell arrays one time by using first data that targets the plurality of memory cell arrays;
outputting second data having a greater number of bits than the first data by reading, at one time, data written to the plurality of memory cell arrays; and
performing a comparison in units of bits confirming whether the second data is appropriate by using the first data.
